(19) United States
(12) Patent Application Publication
(10) Pub. No.: US 2023/0317497 A1
(43) Pub. Date: Oct. 5, 2023

(54) DISPLAY APPARATUS

(71) Applicant: AUO Corporation, Hsinchu (TW)

(72) Inventors: Bo-Chen Chen, Hsinchu (TW); Yu Ting Chen, Hsinchu (TW)

(73) Assignee: AUO Corporation, Hsinchu (TW)

(21) Appl. No.: 18/076,396

(22) Filed: Dec. 7, 2022

Related U.S. Application Data
(60) Provisional application No. 63/326,437, filed on Apr. 1, 2022.

(30) Foreign Application Priority Data
Jul. 22, 2022 (TW) 111127574

(51) Int. Cl. H01L 21/683; H01L 25/075; H01L 33/62

(52) U.S. Cl. CPC H01L 21/6835; H01L 25/0753; H01L 33/62; H01L 2221/68354; H01L 2221/68368; H01L 2221/68381; H01L 2933/0066

(57) ABSTRACT

A display apparatus includes a carrier base, a pixel driving circuit, an insulating layer, a pad group, a light-emitting element, and a first fixing element. The pixel driving circuit is disposed on the carrier base. The insulating layer is disposed on the pixel driving circuit. The pad group is disposed on the insulating layer and is electrically connected to the pixel driving circuit. The light-emitting element is electrically connected to the pad group. The first fixing element is disposed on the insulating layer and at least located on two opposite sides of the pad group. In a direction perpendicular to the carrier base, the light-emitting element has a height H_{LED}, the first fixing element has a height H_{PS1}, a pad of the pad group has a thickness H_{PAD}. H_{LED}, H_{PS1}, and H_{PAD} satisfy:

$${H}_{L E D} \underline{\leq } {H}_{P S 1} \underline{\leq } 1.4 ⋅ \left({H}_{L E D} + {H}_{P A D}\right) .$$

Or, H_{LED}, H_{PS1}, and H_{PAD} satisfy:

$${H}_{L E D} + 90 μ m \underline{\leq } {H}_{P S 1} \underline{\leq } 1.4 ⋅ \left({H}_{L E D} + {H}_{P A D} + 90 μ m\right) .$$

### CROSS-REFERENCE TO RELATED APPLICATION

This application claims the priority benefit of the U.S. Provisional Application Serial No. 63/326,437, filed on Apr. 1, 2022 and Taiwan Application Serial No. 111127574, filed on Jul. 22, 2022. The entirety of each of the above-mentioned patent applications is hereby incorporated by reference herein and made a part of this specification.

### BACKGROUND

### Technical Field

The disclosure relates to an optoelectronic apparatus, and in particular to a display apparatus.

### Description of Related Art

A light-emitting diode display panel includes a driving backplane and multiple light-emitting diode elements transferred on the driving backplane. Inheriting the characteristics of light-emitting diodes, light-emitting diode display panels have the advantages of power saving, high efficiency, high brightness, and fast response time. In addition, compared with organic light-emitting diode display panels, light-emitting diode display panels also have the advantages of easy color adjustment, long luminous life, and no image burn-in. Therefore, the light-emitting diode display panel is regarded as the next generation display technology.

During the manufacturing process of the light-emitting diode display panel, a large amount of light-emitting diode elements on the temporary base should be transferred to the driving backplane, and the electrodes of the light-emitting diode elements should be electrically connected to the pads of the driving backplane. When transferring the light-emitting diode element, laser may be used to irradiate the temporary base and the light-emitting diode element, so that the electrode of the light-emitting diode element and the pad of the driving backplane are eutectic bonded. The light-emitting element and the base of the temporary base are then separated. However, during the process of irradiating the temporary base with the laser, the adhesive layer of the temporary base will be heated to cause thermal expansion, so that the position of the light-emitting diode element disposed on the adhesive layer of the temporary base is shifted. When the position of the light-emitting diode element is shifted, the electrode of the light-emitting diode element cannot be smoothly connected with the pad of the driving backplane, resulting in that part of the subsequently formed display apparatus cannot be lit.

### SUMMARY

The disclosure provides a manufacturing method of a display apparatus capable of improving the bond yield.

The disclosure provides a display apparatus with high yield.

The manufacturing method of a display apparatus is described below. A light-emitting element substrate is provided. The light-emitting element substrate includes a temporary base, an adhesive layer, and a light-emitting element. The adhesive layer is disposed on the temporary base and the light-emitting element is disposed on the adhesive layer. A driving backplane is provided. The driving backplane includes a carrier base, a pixel driving circuit, an insulating layer, a pad group, and a first fixing element. The pixel driving circuit is disposed on the carrier base. The insulating layer is disposed on the pixel driving circuit. The pad group is disposed on the insulating layer and is electrically connected to the pixel driving circuit. The first fixing element is disposed on the insulating layer and at least located on two opposite sides of the pad group. The light-emitting element of the light-emitting element substrate is transferred onto the driving backplane. The light-emitting element is electrically connected to the pad group of the driving backplane. During a part of a process of transferring the light-emitting element of the light-emitting element substrate onto the driving backplane, the first fixing element abuts the adhesive layer of the light-emitting element substrate.

A display apparatus of the disclosure includes a carrier base, a pixel driving circuit, an insulating layer, a pad group, a light-emitting element, and a first fixing element. The pixel driving circuit is disposed on the carrier base. The insulating layer is disposed on the pixel driving circuit. The pad group is disposed on the insulating layer and is electrically connected to the pixel driving circuit. The light-emitting element is electrically connected to the pad group. The first fixing element is disposed on the insulating layer and at least located on two opposite sides of the pad group. The light-emitting element includes an electrode and a solder disposed on the electrode. The solder is located between the electrode and a pad of the pad group. The electrode of the light-emitting element and a surface of the light-emitting element facing away from the carrier base has a distance H_{LED} in a direction perpendicular to the carrier base. The first fixing element has a height H_{PS1} in the direction perpendicular to the carrier base. The solder has a thickness H_{PAD} in the direction perpendicular to the carrier base, H_{LED}, H_{PS1}, and H_{PAD} satisfy:

$${H}_{L E D} \underline{\leq } {H}_{P S 1} \underline{\leq } 1.4 ⋅ \left({H}_{L E D} + {H}_{P A D}\right) .$$

Or, H_{LED}, H_{PS1}, and H_{PAD} satisfy:

$${\text{H}}_{\text{LED}} + 90 μ \text{m} ≦ {\text{H}}_{\text{PS1}} ≦ 1.4 ⋅ \left({\text{H}}_{\text{LED}} + {\text{H}}_{\text{PAD}} + 90 μ \text{m}\right) .$$

### BRIEF DESCRIPTION OF THE DRAWINGS

FIG. 1A to FIG. 1C are cross-sectional schematic views showing a manufacturing flow of a display apparatus according to an embodiment of the disclosure.

FIG. 2 is a top schematic view of a display apparatus according to an embodiment of the disclosure.

FIG. 3 is a top schematic view of a display apparatus according to another embodiment of the disclosure.

FIG. 4 is a top schematic view of a display apparatus according to yet another embodiment of the disclosure.

FIG. 5 is a top schematic view of a display apparatus according to another embodiment of the disclosure.

FIG. 6A to FIG. 6C are cross-sectional schematic views showing a manufacturing flow of a display apparatus according to an embodiment of the disclosure.

FIG. 7 is a top schematic view of a display apparatus according to an embodiment of the disclosure.

FIG. 8 is a top schematic view of a display apparatus according to another embodiment of the disclosure.

FIG. 9A to FIG. 9C are cross-sectional schematic views of a manufacturing flow of a display apparatus according to another embodiment of the disclosure.

FIG. 10 is a top schematic view of a display apparatus according to yet another embodiment of the disclosure.

FIG. 11 is a top schematic view of a first fixing element according to another embodiment of the disclosure.

FIG. 12 is a side schematic view of a first fixing element according to another embodiment of the disclosure.

FIG. 13 is a top schematic view of a first fixing element according to an embodiment of the disclosure.

FIG. 14 is a side schematic view of a first fixing element according to an embodiment of the disclosure.

FIG. 15 is a top schematic view of a first fixing element according to another embodiment of the disclosure.

FIG. 16 is a side schematic view of a first fixing element according to another embodiment of the disclosure.

FIG. 17 is a top schematic view of a first fixing element according to yet another embodiment of the disclosure.

FIG. 18 is a side schematic view of a first fixing element according to yet another embodiment of the disclosure.

FIG. 19 is a top schematic view of a first fixing element according to another embodiment of the disclosure.

FIG. 20 is a side schematic view of a first fixing element according to another embodiment of the disclosure.

FIG. 21 is a top schematic view of a first fixing element according to an embodiment of the disclosure.

FIG. 22 is a side schematic view of a first fixing element according to an embodiment of the disclosure.

### DESCRIPTION OF THE EMBODIMENTS

References of the exemplary embodiments of the disclosure are to be made in detail. Examples of the exemplary embodiments are illustrated in the drawings. If applicable, the same reference numerals in the drawings and the descriptions indicate the same or similar parts.

It should be understood that when an element such as a layer, a film, an area, or a substrate is indicated to be “on” another element or “connected to” another element, it may be directly on another element or connected to another element, or an element in the middle may exist. In contrast, when an element is indicated to be “directly on another element” or “directly connected to” another element, an element in the middle does not exist. As used herein, “to connect” may indicate to physically and/or electrically connect. Furthermore, “to electrically connect” or “to couple” may also be used when other elements exist between two elements.

The usages of “approximately”, “similar to”, or “substantially” indicated throughout the specification include the indicated value and an average value having an acceptable deviation range, which is a certain value confirmed by people skilled in the art, and is a certain amount considered the discussed measurement and measurement-related deviation (that is, the limitation of measurement system). For example, “approximately” may indicate to be within one or more standard deviations of the indicated value, or being within ±30%, ±20%, ±10%, ±5%. Furthermore, the usages of “approximately”, “similar to”, or “substantially” indicated throughout the specification may refer to a more acceptable deviation scope or standard deviation depending on optical properties, etching properties, or other properties, and all properties may not be applied with one standard deviation.

Unless otherwise defined, all terms (including technical and scientific terms) used herein have the same meaning as that commonly understood by one of ordinary skill in the art to which this disclosure belongs. It should be further understood that terms such as those defined in commonly used dictionaries should be construed as having meanings consistent with their meanings in the context of the related art and the disclosure, and are not to be construed as idealized or excessive formal meaning, unless expressly defined as such herein.

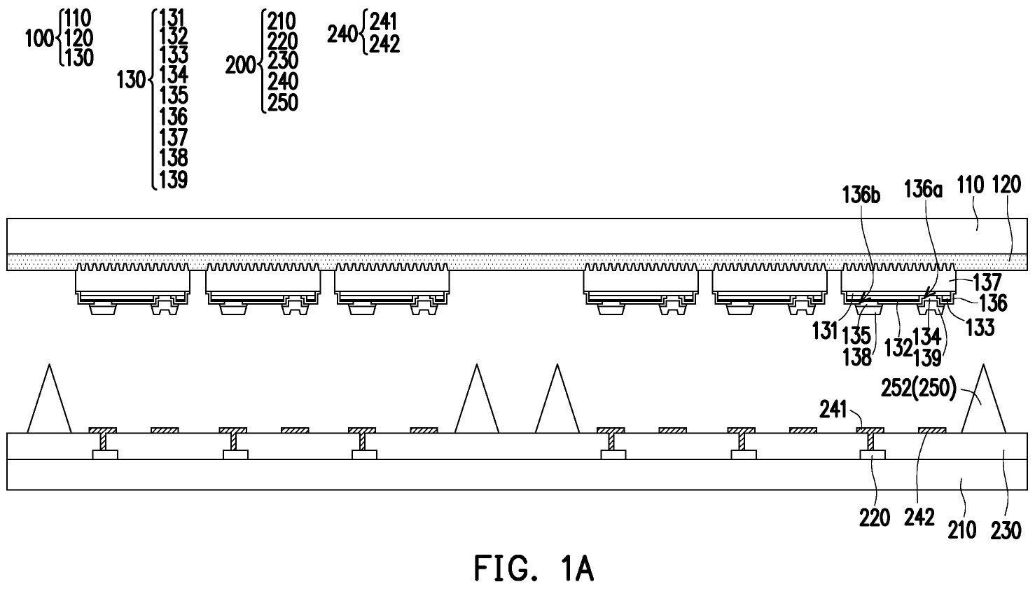

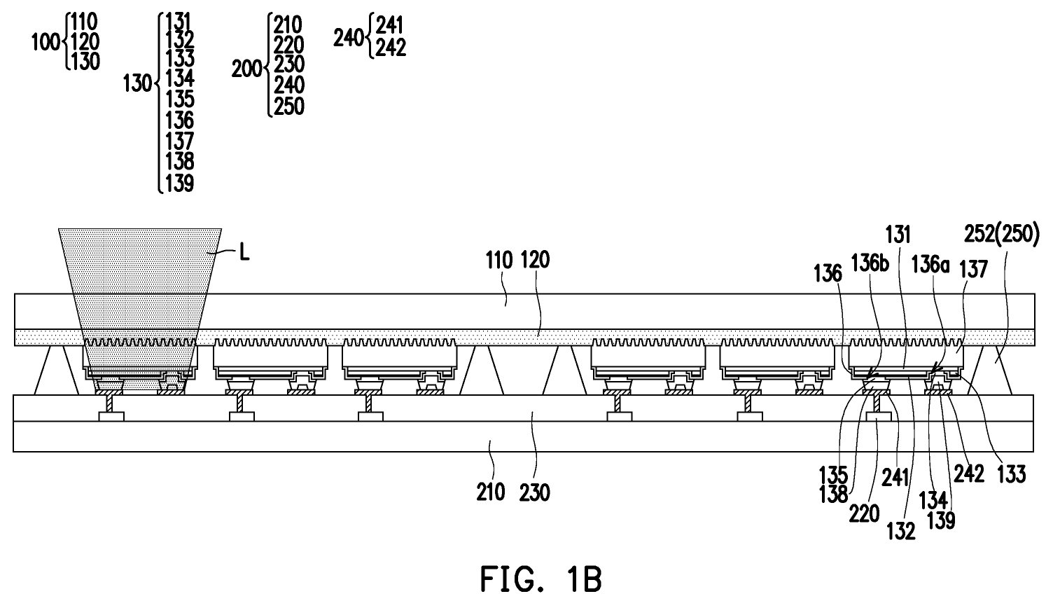

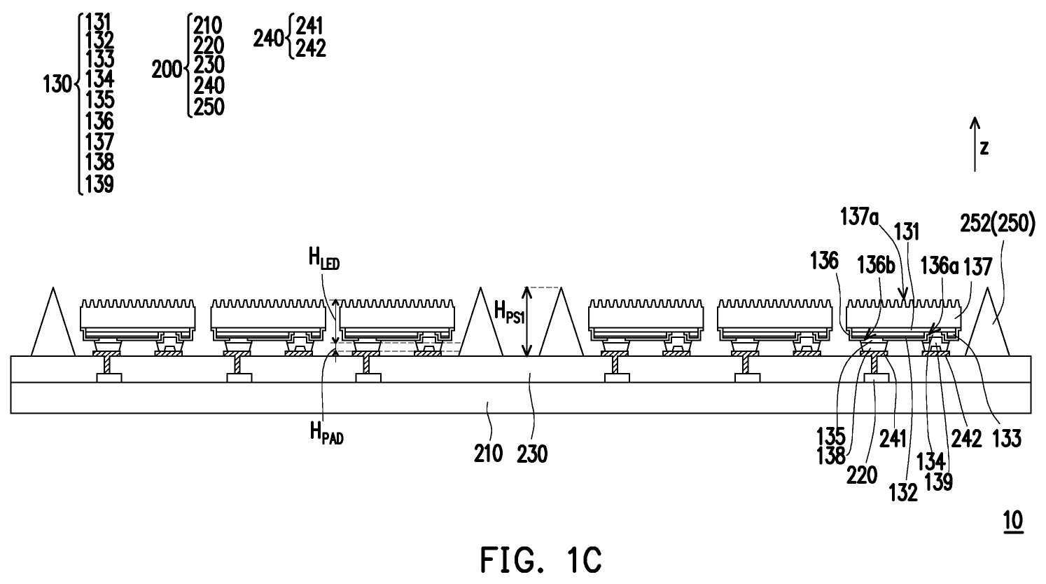

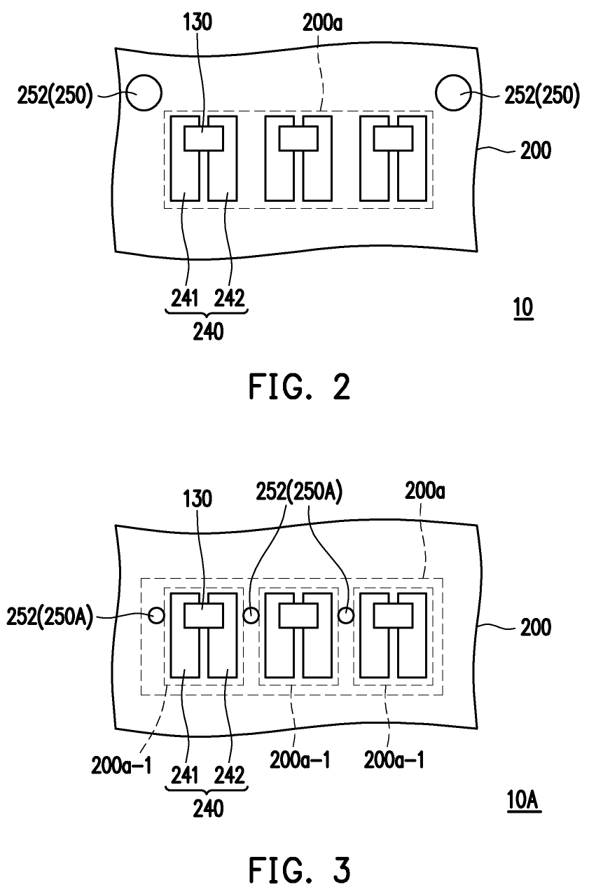

FIG. 1A to FIG. 1C are cross-sectional schematic views showing a manufacturing flow of a display apparatus according to an embodiment of the disclosure. FIG. 2 is a top schematic view of a display apparatus according to an embodiment of the disclosure.

Referring to FIG. 1A, first, a light-emitting element substrate 100 is provided. The light-emitting element substrate 100 includes a temporary base 110, an adhesive layer 120, and a light-emitting element 130. The adhesive layer 120 is disposed on the temporary base 110. The light-emitting element 130 is disposed on the adhesive layer 120. The adhesive layer 120 is located between the temporary base 110 and the light-emitting element 130.

In detail, in this embodiment, the light-emitting element 130 includes a first semiconductor layer 131, a second semiconductor layer 132, an active layer 133 disposed between the first semiconductor layer 131 and the second semiconductor layer 132, and multiple electrodes 134 and electrodes 135 electrically connected to the first semiconductor layer 131 and the second semiconductor layer 132, respectively. The active layer 133 of the light-emitting element 130 is located between the temporary base 110 and the electrodes 134 and the electrodes 135 of the light-emitting element 130. That is to say, the electrodes 134 and the electrodes 135 of the light-emitting element 130 face outward. In this embodiment, the light-emitting element 130 further includes multiple solders 138 and solders 139 respectively disposed on the electrodes 135 and the electrodes 134. For example, the material of the solders 138 and the solders 139 may include tin (Sn), but the disclosure is not limited thereto.

In this embodiment, the light-emitting element 130 may further include an insulating layer 136, which is disposed on the second semiconductor layer 132 and includes multiple contact windows 136a and contact windows 136b that overlap the first semiconductor layer 131 and the second semiconductor layer 132, respectively. The electrodes 134 and the electrodes 135 are electrically connected to the first semiconductor layer 131 and the second semiconductor layer 132 through the contact windows 136a and the contact windows 136b of the insulating layer 136, respectively. In this embodiment, the light-emitting element 130 may optionally include an epitaxial layer 137. The first semiconductor layer 131 is formed on the epitaxial layer 137. The epitaxial layer 137 is located between the adhesive layer 120 and the first semiconductor layer 131, and the first semiconductor layer 131 is located between the epitaxial layer 137 and the active layer 133. For example, in this embodiment, the epitaxial layer 137 is undoped gallium nitride, the first semiconductor layer 131 is n-type gallium nitride, the active layer 133 is a multiple-quantum well, and the second semiconductor layer 132 is p-type gallium nitride, but the disclosure is not limited thereto.

Referring to FIG. 1A, next, a driving backplane 200 is provided. The driving backplane 200 includes a carrier base 210, a pixel driving circuit 220, an insulating layer 230, and a pad group 240. The pixel driving circuit 220 is disposed on the carrier base 210. The insulating layer 230 is disposed on the pixel driving circuit 220. The pad group 240 is disposed on the insulating layer 230 and is electrically connected to the pixel driving circuit 220. The pad group 240 includes multiple pads 241 and pads 242 separated from each other in structure.

For example, in this embodiment, the pixel driving circuit 220 may include a data line (not shown), a scanning line (not shown), a power line (not shown), a common line (not shown), a first transistor (not shown), a second transistor (not shown), and a capacitor (not shown). A first end of the first transistor is electrically connected to the data line. A control end of the first transistor is electrically connected to the scanning line. A second end of the first transistor is electrically connected to a control end of the second transistor. A first end of the second transistor is electrically connected to the power line. The capacitor is electrically connected to the second end of the first transistor and the first end of the second transistor. A second end of the second transistor is electrically connected to the pads 241 and the pads 242 of the pad group 240. The common line is electrically connected to the other one of the pads 241 and the pads 242 of the pad group 240. However, the disclosure is not limited thereto. In other embodiments, the pixel driving circuit 220 may also be other types of circuits.

Referring to FIG. 1A and FIG. 2, it is worth noting that the driving backplane 200 further includes a first fixing element 250 disposed on the insulating layer 230 and at least located on two opposite sides of the pad group 240. For example, in this embodiment, the driving backplane 200 includes a pixel area 200a (as shown in FIG. 2). The pad groups 240 are disposed in the pixel area 200a. The pad groups 240 in the same pixel area 200a are configured to electrically connect with the light-emitting elements 130 that emit light in different colors. The first fixing element 250 may include multiple fixing structures 252. The fixing structures 252 are respectively disposed on two opposite sides of the pad groups 240 in the same pixel area 200a. However, the disclosure is not limited thereto. In other embodiments, the first fixing element 250 may also be configured in other ways.

In this embodiment, the fixing structure 252 of the first fixing element 250 may optionally be a cone. However, the disclosure is not limited thereto. In other embodiments, the fixing structure 252 may also in other shapes, such as but not limited to: a cylinder, a triangular column, a quadrangular column, a trapezoidal quadrangular column, and other polygonal columns or a retaining wall. The material of the first fixing element 250 is preferably an elastic and compressible material. For example, in this embodiment, the material of the first fixing element 250 may be a photoresist, but the disclosure is not limited thereto. In this embodiment, a compression ratio of the first fixing element 250 may fall within a range of 60% to 90%, but the disclosure is not limited thereto. In this embodiment, a ratio of the number of the first fixing element 250 to the pads 241 and the pads 242 may fall within a range of 1/64 to 1, but the disclosure is not limited thereto.

Referring to FIG. 1A to FIG. 1C, then, the light-emitting element 130 of the light-emitting element substrate 100 is transferred onto the driving backplane 200, and the light-emitting element 130 is electrically connected to the pad group 240 of the driving backplane 200. In particular, during a part of a process of transferring the light-emitting element 130 onto the driving backplane 200, the first fixing element 250 of the driving backplane 200 abuts the adhesive layer 120 of the light-emitting element substrate 100.

Referring to FIG. 1B, in detail, in this embodiment, a laser L may be made to penetrate the temporary base 110 and the adhesive layer 120 of the light-emitting element substrate 100 in sequence and irradiate the solders 138 and the solders 139 of the light-emitting element 130 and the pads 241 and 242 of the driving backplane 200, so that the solders 138 and the solders 139 of the light-emitting element 130 and the pads 241 and 242 of the driving backplane 200 are joined.

It is worth noting that during a period when the laser L irradiates the solders 138 and the solders 139 of the light-emitting element 130 and the pads 241 and the pads 242 of the driving backplane 200, the first fixing element 250 continues to abut the adhesive layer 120 of the light-emitting element substrate 100. That is to say, the first fixing element 250 functions analogously to a fixing anchor, which may fix the adhesive layer 120, so that the light-emitting element 130 disposed on the adhesive layer 120 is not easily shift from the original position. In this way, during a process of joining the light-emitting element 130 and the driving backplane 200 by the laser L, although the adhesive layer 120 is heated by the irradiation of the laser L, the adhesive layer 120 is not prone to excessive thermal expansion and contraction, which cause the light-emitting element 130 to easily shift from the original position. Thus, the bonding yield between the light-emitting element 130 and the driving backplane 200 is significantly improved.

Referring to FIG. 1A and FIG. 1B, in addition, in this embodiment, the first fixing element 250 may also be used as an alignment stop between the light-emitting element 130 and the pad group 240 to assist the alignment between the light-emitting element 130 and the pad group 240. Furthermore, in response to a great difference in coplanarity between the light-emitting element substrate 100 and the driving backplane 200, which results in the light-emitting element substrate 100 needing to press on the driving backplane 200 with greater force, the first fixing element 250 may also be used as a buffer material.

Referring to FIG. 1B and FIG. 1C, during a process of joining the light-emitting element 130 to the driving backplane 200, an interface between a part of the adhesive layer 120 irradiated by the laser L and the temporary base 110 is dissociated. Thus, the light-emitting element 130 is separated from the temporary base 110 and is transferred onto the driving backplane 200 to form the display apparatus 10.

Referring to FIG. 1C, the light-emitting element 130 includes an electrode 135 and a solder 138 disposed on the electrode 135, and the solder 138 is located between the electrode 135 and the pad 241 of the pad group 240. The electrode 135 of the light-emitting element 130 and a surface 137a of the light-emitting element 130 facing away from the carrier base 210 has a distance H_{LED} in a direction z perpendicular to the carrier base. The first fixing element 250 has a height H_{PS1} in the direction z perpendicular to the carrier base 210, The solder 138 has a thickness H_{PAD} in the direction z perpendicular to the carrier base 210, In this embodiment, H_{LED}, H_{PS1}, and H_{PAD} satisfy:

$${\text{H}}_{\text{LED}} ≦ {\text{H}}_{\text{PS1}} ≦ 1.4 ⋅ \left({\text{H}}_{\text{LED}} + {\text{H}}_{\text{PAD}}\right) .$$

It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

FIG. 3 is a top schematic view of a display apparatus according to another embodiment of the disclosure. The display apparatus 10A of FIG. 3 is similar to the display apparatus 10 of FIG. 2. The difference between the two is that the position of the fixing structure 252 of the first fixing element 250A of FIG. 3 is different from the position of the fixing structure 252 of the first fixing element 250 of FIG. 2.

Referring to FIG. 3, the pixel area 200a includes multiple sub-pixel areas 200a-1, and the pad groups 240 are respectively disposed in the sub-pixel areas 200a-1. Different from the embodiment of FIG. 2, in this embodiment, a corresponding fixing structure 252 may be provided next to each sub-pixel area 200a-1.

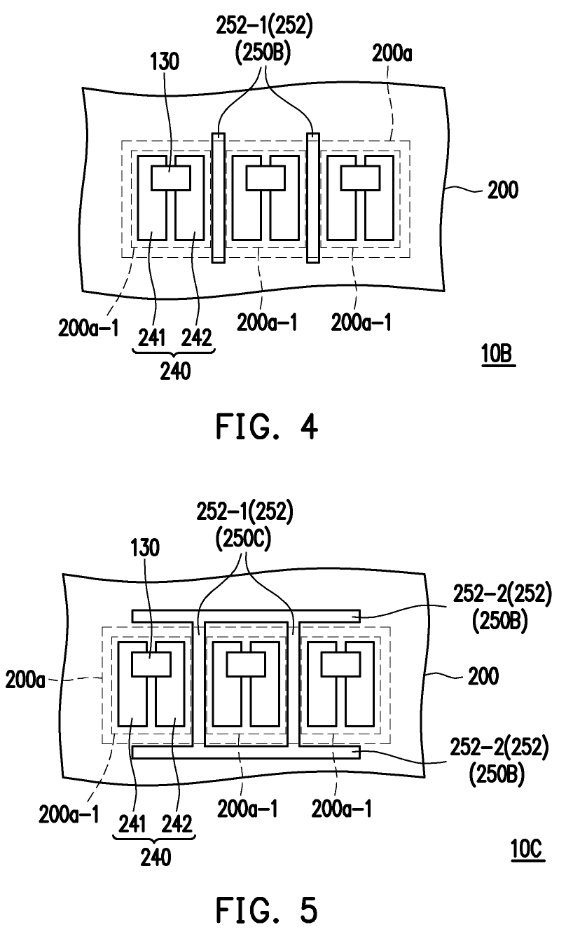

FIG. 4 is a top schematic view of a display apparatus according to yet another embodiment of the disclosure. The display apparatus 10B of FIG. 4 is similar to the display apparatus 10 of FIG. 2. The difference between the two is that the first fixing element 250B of FIG. 4 is different from the first fixing element 250 of FIG. 2. Referring to FIG. 4, in particular, in this embodiment, the fixing structure 252 of the first fixing element 250B may be a retaining wall. Furthermore, in this embodiment, the fixing structure 252 may optionally include multiple vertical retaining walls 252-1 interspersed between the sub-pixel areas 200a-1.

FIG. 5 is a top schematic view of a display apparatus according to another embodiment of the disclosure. The display apparatus 10C of FIG. 5 is similar to the display apparatus 10B of FIG. 4. The difference between the two is that the first fixing element 250C of FIG. 5 is different from the first fixing element 250B of FIG. 4. in particular, in this embodiment, the first fixing element 250C includes multiple horizontal retaining walls 252-2 intersecting with the vertical retaining walls 252-1 in addition to the vertical retaining walls 252-1.

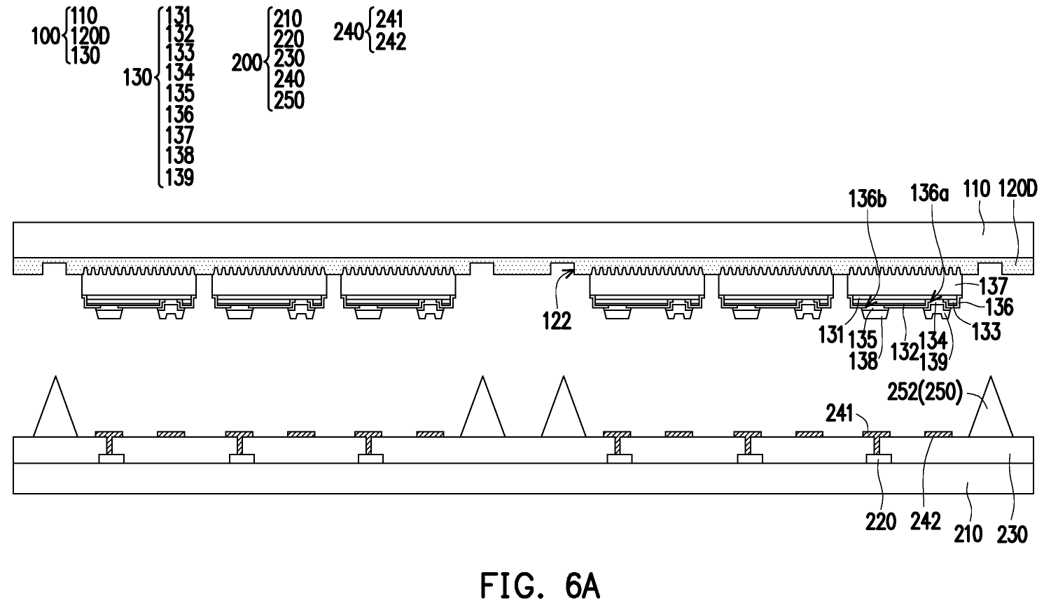

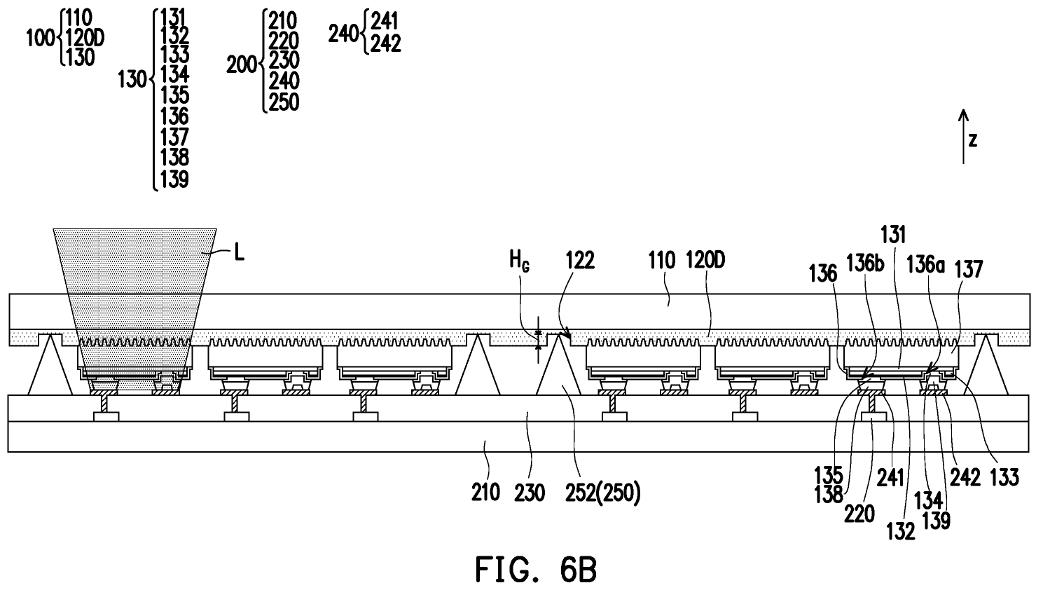

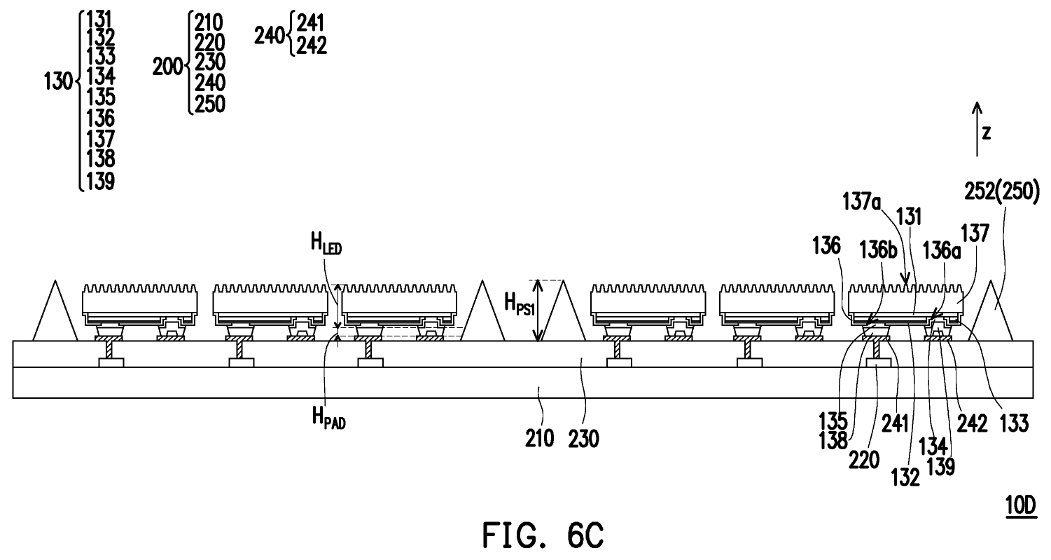

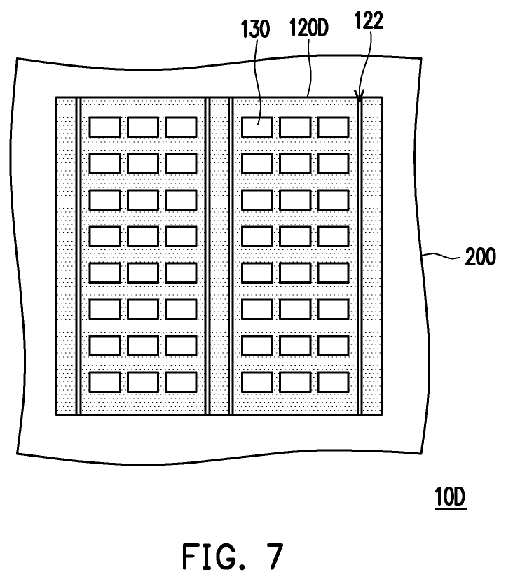

FIG. 6A to FIG. 6C are cross-sectional schematic views showing a manufacturing flow of a display apparatus according to an embodiment of the disclosure. FIG. 7 is a top schematic view of a display apparatus according to an embodiment of the disclosure. FIG. 7 corresponds to FIG. 6B and shows the depression 122 of the adhesive layer 120D of FIG. 6B. The first fixing element 250 is omitted in FIG. 7.

The manufacturing flow of the display apparatus 10D of FIG. 6A to FIG. 6C is similar to the manufacturing flow of the display apparatus 10 of FIGS. 1A to 1C. The difference between the two is described below. Please refer to FIG. 6A, FIG. 6B and FIG. 7, in this embodiment, the adhesive layer 120D includes a depression 122. During a part of a process of transferring the light-emitting element 130 onto the driving backplane 200, a part of the first fixing element 250 protrudes into the depression 122 of the adhesive layer 120D of the light-emitting element substrate 100. Facilitated by the depression 122 of the adhesive layer 120D, during a process of engaging with the first fixing element 250, the first fixing element 250 may fix the adhesive layer 120D better. Thus, the thermal expansion and contraction caused by the laser L to the adhesive layer 120D is reduced, thereby reducing the shifting of the emitting element 130.

Referring to FIG. 6B, the depression 122 of the adhesive layer 120D has a depth H_{G} in the direction z perpendicular to the temporary base 110. Referring to FIG. 6C, the electrode 135 of the light-emitting element 130 and a surface 137a of the light-emitting element 130 facing away from the carrier base 210 has a distance H_{LED} in a direction z perpendicular to the carrier base. The first fixing element 250 has a height H_{PS1} in the direction z perpendicular to the carrier base 210. The solder 138 has a thickness H_{PAD} in the direction z perpendicular to the carrier base 210. Referring to FIG. 6B and FIG. 6C, in this embodiment, H_{LED}, H_{PS1}, H_{PAD}, and H_{G} satisfy:

$${H}_{L E D} + {H}_{G} \underline{\leq } {H}_{P S I} \underline{\leq } 1.4 ⋅ \left({H}_{L E D} + {H}_{P A D} + {H}_{G}\right) .$$

Referring to FIG. 6B, in particular, in this embodiment, 0 µm<H_{G}≦90 µm. Referring to FIG. 6C, that is, in this embodiment, H_{LED}, H_{PS1}, and H_{PAD} satisfy:

$${H}_{L E D} + 90 μ m \underline{\leq } {H}_{P S 1} \underline{\leq } 1.4 ⋅ \left({H}_{L E D} + {H}_{P A D} + 90 μ m\right) .$$

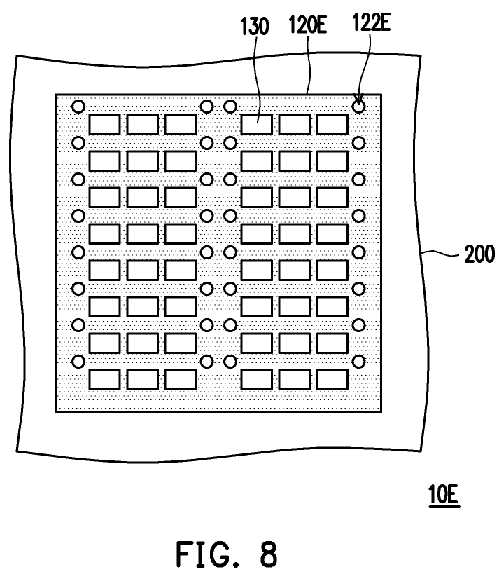

FIG. 8 is a top schematic view of a display apparatus according to another embodiment of the disclosure. FIG. 8 further shows a depression 122E of an adhesive layer 120E corresponding to a display apparatus 10E. Referring to FIG. 7 and FIG. 8. The embodiment of FIG. 8 is similar to the embodiment of FIG. 7, the difference between the two is that the depression 122E of the adhesive layer 120E in FIG. 8 is different from the depression 122 in the adhesive layer 120D in FIG. 7. In particular, in the embodiment of FIG. 7, the depression 122 of the adhesive layer 120D is in a form of an elongated strip, while in the embodiment of FIG. 8, the depression 122E of the adhesive layer 120E is in a form of a spot.

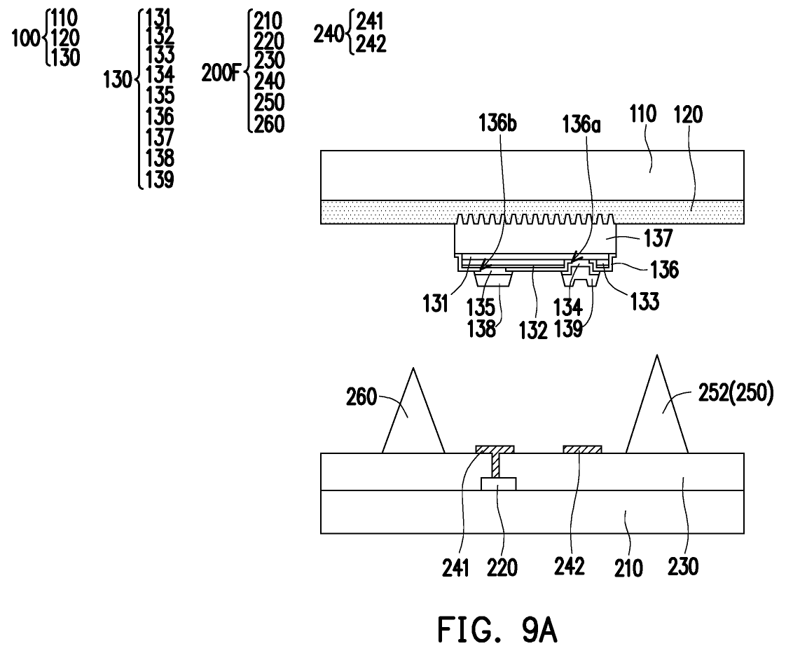

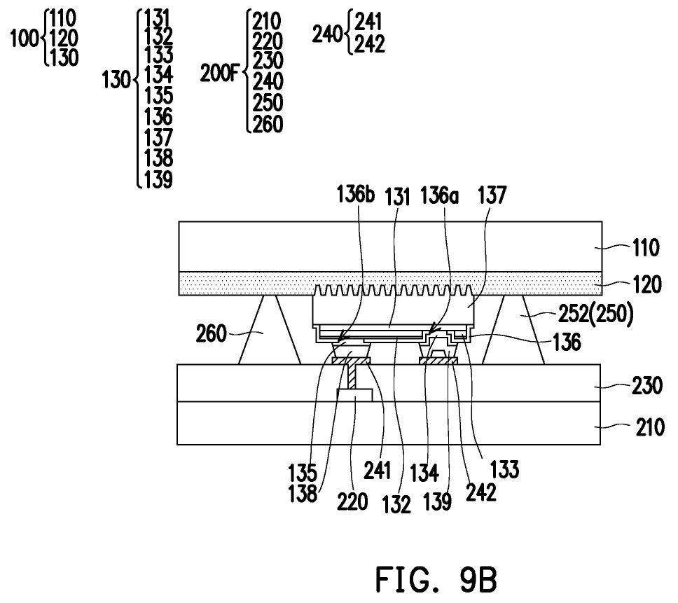

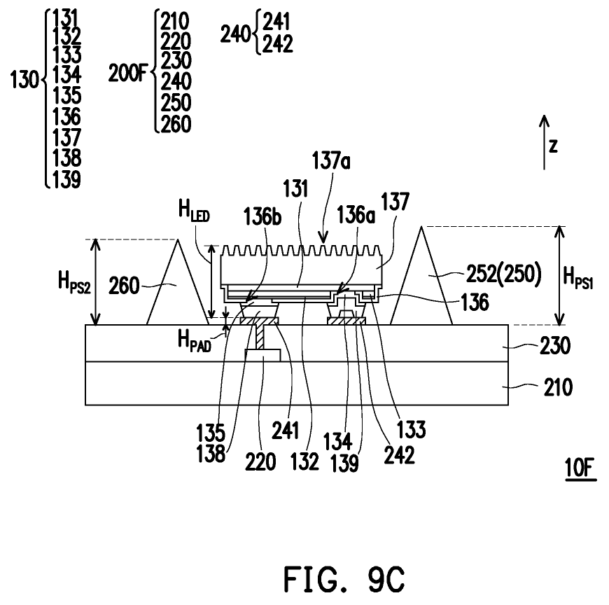

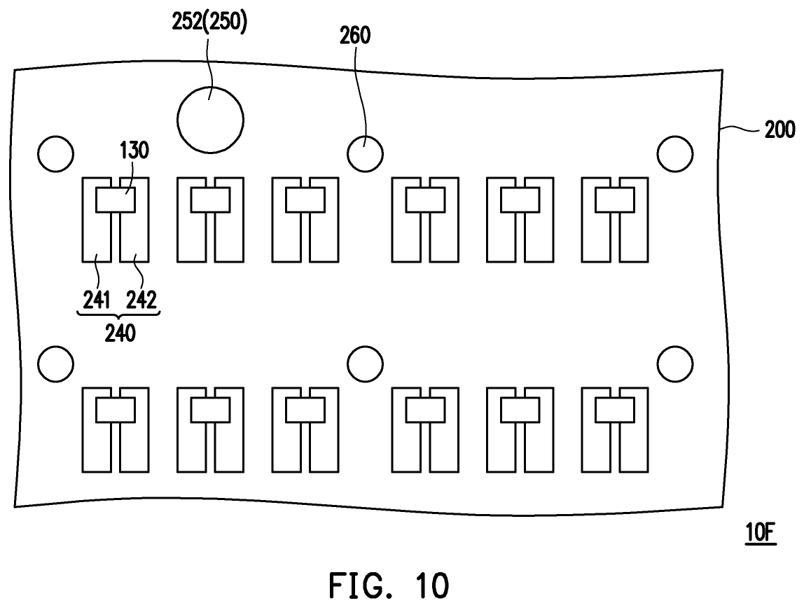

FIG. 9A to FIG. 9C are cross-sectional schematic views of a manufacturing flow of a display apparatus according to another embodiment of the disclosure. FIG. 10 is a top schematic view of a display apparatus according to yet another embodiment of the disclosure.

The display apparatus 10F and the manufacturing flow thereof of FIG. 9A to FIG. 9C and FIG. 10 is similar to the display apparatus 10 of FIG. 1A to FIG. 1C and FIG. 2. The difference between the two is that in the embodiment of FIG. 9A to FIG. 9C and FIG. 10, the driving backplane 200F further includes a second fixing element 260, which is disposed on the insulating layer 230 and located outside the pad group 240 and the first fixing element 250. The second fixing element 260 has a height H_{PS2} in the direction z perpendicular to the carrier base 210, where H_{PS2}> H_{LED} and H_{PS2}< H_{PS1}. Referring to FIG. 9B, in this embodiment, in response to the light-emitting element substrate 100 pressing on the driving backplane 200F with greater force, the second fixing element 260 may be used as a buffer material. Thus, the first fixing element 250 is prevented from being over-compressed, deformed, and unable to recover the elasticity thereof. For example, in this embodiment, a ratio of the number of the first fixing element 250 to the second fixing element 260 may be 1:8 or 1:32, but the disclosure is not limited thereto.

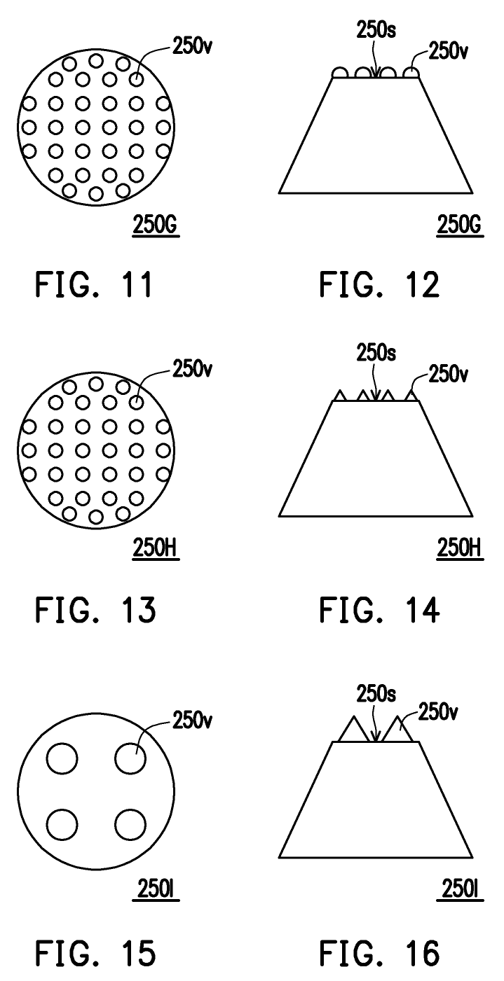

FIG. 11 is a top schematic view of a first fixing element according to another embodiment of the disclosure. FIG. 12 is a side schematic view of a first fixing element according to another embodiment of the disclosure.

The first fixing element 250G of FIG. 11 and FIG. 12 is similar to the first fixing element 250 described above. The differences between the two are that the first fixing element 250G of FIG. 11 and FIG. 12 includes a surface 250s facing away from the carrier base 210 (as shown in FIG. 1B), and the surface 250s includes multiple micro bumps 250v. Referring to FIG. 1B, FIG. 11, and FIG. 12, during a part of a process of transferring the light-emitting element 130 of the light-emitting element substrate 100 onto the driving backplane 200, the micro bump 250v of the first fixing element 250G may protrudes into the adhesive layer 120 of the light-emitting element substrate 100. Thus, the first fixing element 250G may fix the adhesive layer 120 better. The thermal expansion and contraction caused by the laser L to the adhesive layer 120 is reduced, thereby reducing the shifting of the emitting element 130. In this embodiment, the micro bump 250v is, for example, an arc-shaped convex structure, but the disclosure is not limited thereto.

FIG. 13 is a top schematic view of a first fixing element according to an embodiment of the disclosure. FIG. 14 is a side schematic view of a first fixing element according to an embodiment of the disclosure. The first fixing element 250H of FIG. 13 and FIG. 14 is similar to the first fixing element 250G of FIG. 11 and FIG. 12. The difference between the two is that the micro bump 250v of the first fixing element 250H of FIG. 13 and FIG. 14 is a sharp convex structure.

FIG. 15 is a top schematic view of a first fixing element according to another embodiment of the disclosure. FIG. 16 is a side schematic view of a first fixing element according to another embodiment of the disclosure. The first fixing element 250I of FIG. 15 and FIG. 16 is similar to the first fixing element 250H of FIG. 13 and FIG. 14. The differences between the two are that the volume of the micro bump 250v of the first fixing element 250I of FIG. 15 and FIG. 16 is greater than the volume of the micro bump 250v of the first fixing element 250H of FIG. 13 and FIG. 14, and the disposition density of the micro bumps 250v of the first fixing element 250I of FIG. 15 and FIG. 16 is smaller than that of the micro bumps 250v of the first fixing element 250H of FIG. 13 and FIG. 14.

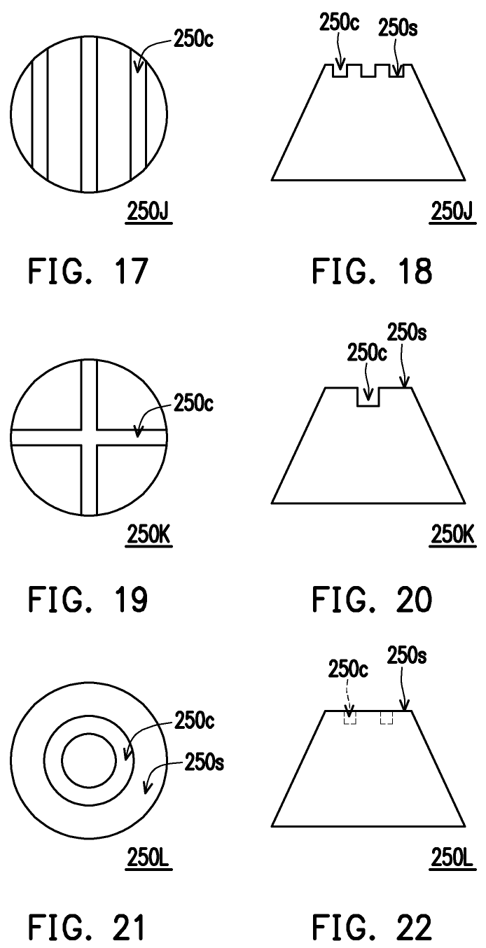

FIG. 17 is a top schematic view of a first fixing element according to yet another embodiment of the disclosure. FIG. 18 is a side schematic view of a first fixing element according to yet another embodiment of the disclosure.

The first fixing element 250J of FIG. 17 and FIG. 18 is similar to the first fixing element 250 described above. The differences between the two are that the first fixing element 250J of FIG. 17 and FIG. 18 includes a surface 250s facing away from the carrier base 210 (as shown in FIG. 1B), and the surface 250s includes at least one groove 250c. Referring to FIG. 1B, FIG. 17 and FIG. 18, during a part of a process of transferring the light-emitting element 130 of the light-emitting element substrate 100 onto the driving backplane 200, a part of the adhesive layer 120 of the light-emitting element substrate 100 trapped in the least one groove 250c of the first fixing element 250J. Thus, the first fixing element 250J may fix the adhesive layer 120 better. The thermal expansion and contraction caused by the laser L to the adhesive layer 120 is reduced, thereby reducing the shifting of the emitting element 130. In this embodiment, at least one groove 250c of the first fixing element 250J is, for example, multiple lateral grooves, but the disclosure is not limited thereto.

FIG. 19 is a top schematic view of a first fixing element according to another embodiment of the disclosure. FIG. 20 is a side schematic view of a first fixing element according to another embodiment of the disclosure. The first fixing element 250K of FIG. 19 and FIG. 20 is similar to the first fixing element 250J of FIG. 17 and FIG. 18. The difference between the two is that the at least one groove 250c of the first fixing element 250K of FIG. 19 and FIG. 20 includes multiple grooves that intersects with each other.

FIG. 21 is a top schematic view of a first fixing element according to an embodiment of the disclosure. FIG. 22 is a side schematic view of a first fixing element according to an embodiment of the disclosure. The first fixing element 250L of FIG. 21 and FIG. 22 is similar to the first fixing element 250J of FIG. 17 and FIG. 18. The difference between the two is that the at least one groove 250c of the first fixing element 250L of FIG. 21 and FIG. 22 includes a ring-shaped groove.

What is claimed is:

1. A manufacturing method for a display apparatus, comprising:
providing a light-emitting element substrate, wherein the light-emitting element substrate comprises a temporary base, an adhesive layer, and a light-emitting element, the adhesive layer is disposed on the temporary base, and the light-emitting element is disposed on the adhesive layer;
providing a driving backplane, wherein the driving backplane comprises a carrier base, a pixel driving circuit, an insulating layer, a pad group, and a first fixing element, the pixel driving circuit is disposed on the carrier base, the insulating layer is disposed on the pixel driving circuit, the pad group is disposed on the insulating layer and is electrically connected to the pixel driving circuit, and the first fixing element is disposed on the insulating layer and at least located on two opposite sides of the pad group; and
transferring the light-emitting element of the light-emitting element substrate onto the driving backplane, and electrically connecting the light-emitting element to the pad group of the driving backplane, wherein during a part of a process of transferring the light-emitting element of the light-emitting element substrate onto the driving backplane, the first fixing element abuts the adhesive layer of the light-emitting element substrate.

2. The manufacturing method for the display apparatus according to claim 1, wherein transferring the light-emitting element of the light-emitting element substrate onto the driving backplane and electrically connecting the light-emitting element to the pad group of the driving backplane comprises:
irradiating a laser to penetrate the temporary base and the adhesive layer of the light-emitting element substrate in sequence, and irradiating an electrode of the light-emitting element and a pad of the pad group of the driving backplane, thereby bonding the electrode of the light-emitting element and the pad of the driving backplane, wherein during the laser irradiating the electrode of the light-emitting element and the pad of the driving backplane, the first fixing element continuously abuts the adhesive layer of the light-emitting element substrate.

3. The manufacturing method for the display apparatus according to claim 1, wherein the first fixing element comprises a surface facing away from the carrier base, and the surface comprises a plurality of micro bumps; wherein during the part of the process of transferring the light-emitting element of the light-emitting element substrate onto the driving backplane, the micro bumps of the first fixing element protrude into the adhesive layer of the light-emitting element substrate.

4. The manufacturing method for the display apparatus according to claim 1, wherein the first fixing element comprises a surface facing away from the carrier base, and the surface comprises at least one groove; wherein during the part of the process of transferring the light-emitting element of the light-emitting element substrate onto the driving backplane, a part of the adhesive layer of the light-emitting element substrate is trapped in the at least one groove of the first fixing element.

5. The manufacturing method for the display apparatus according to claim 1, wherein the adhesive layer of the light-emitting element substrate comprises a depression; wherein during the part of the process of transferring the light-emitting element of the light-emitting element substrate onto the driving backplane, a part of the first fixing element protrudes into the depression of the adhesive layer of the light-emitting element substrate.

6. The manufacturing method for the display apparatus according to claim 5, wherein the light-emitting element comprises an electrode and a solder disposed on the electrode, the solder is located between the electrode and a pad of the pad group, the electrode of the light-emitting element and a surface of the light-emitting element facing away from the carrier base has a distance H_{LED} in a direction perpendicular to the carrier base, the depression of the adhesive layer has a depth H_{G} in a direction perpendicular to the temporary base, the first fixing element has a height H_{PS1} in the direction perpendicular to the carrier base, the solder has a thickness H_{PAD} in the direction perpendicular to the carrier base, and H_{LED}+H_{G} ≦H_{PS1} ≦1.4·(H_{LED} +H_{PAD}+H_{G}).

7. The manufacturing method for the display apparatus according to claim 1, wherein the light-emitting element comprises an electrode and a solder disposed on the electrode, the solder is located between the electrode and a pad of the pad group, the electrode of the light-emitting element and a surface of the light-emitting element facing away from the carrier base has a distance H_{LED} in a direction perpendicular to the carrier base, the first fixing element has a height H_{PS1} in the direction perpendicular to the carrier base, the solder has a thickness H_{PAD} in the direction perpendicular to the carrier base, and H_{LED}≦H_{PS1} ≦1.4·(H_{LED} +H_{PAD}).

8. A display apparatus, comprising:
a carrier base;
a pixel driving circuit, disposed on the carrier base;
an insulating layer, disposed on the pixel driving circuit;
a pad group, disposed on the insulating layer and electrically connected to the pixel driving circuit;
a light-emitting element, electrically connected to the pad group; and
a first fixing element, disposed on the insulating layer and at least located on two opposite sides of the pad group;
wherein the light-emitting element comprises an electrode and a solder disposed on the electrode, the solder is located between the electrode and a pad of the pad group, the electrode of the light-emitting element and a surface of the light-emitting element facing away from the carrier base has a distance H_{LED} in a direction perpendicular to the carrier base, the first fixing element has a height H_{PS1} in the direction perpendicular to the carrier base, the solder has a thickness H_{PAD} in the direction perpendicular to the carrier base,
H_{LED}, H_{PS1}, and H_{PAD} satisfy:
$${H}_{L E D} \underline{\leq } {H}_{P S 1} \underline{\leq } 1.4 ⋅ \left({H}_{L E D} + {H}_{P A D}\right) ; \text{or}$$
H_{LED}, H_{PS1}, and H_{PAD} satisfy:
$${H}_{L E D} + 90 μ m \underline{\leq } {H}_{P S 1} \underline{\leq } 1.4 ⋅ \left({H}_{L E D} + {H}_{P A D} + 90 μ m\right)$$
.

9. The display apparatus according to claim 8, wherein the first fixing element comprises a surface facing away from the carrier base, and the surface comprises a plurality of micro bumps.

10. The display apparatus according to claim 8, wherein the first fixing element comprises a surface facing away from the carrier base, and the surface comprises at least one groove.
